(19) United States
(12) Patent Application Publication
(10) Pub. No.: US 2005/0002223 A1
(43) Pub. Date: Jan. 6, 2005

(54) Output driver impedance control for addressable memory devices

(76) Inventors: Paul William Coteus, Yorktown, NY (US); Brian Li Ji, Fishkill, NY (US); Toshiaki Kirihata, Poughkeepsie, NY (US); Joseph Dominick Macri, San Francisco, CA (US); John Michael Ross, Olney, MD (US)

Correspondence Address: Thomas A. Beck, 26 Rockledge Lane, New Milford, CT, 06776, US

(21) Appl. No.: 10/688,744

(22) Filed: Oct. 17, 2003

Related U.S. Application Data
(63) Continuation-in-part of application No. 10/072,346, filed on Feb. 6, 2002.

(51) Int. Cl. G11C 11/00

(52) U.S. Cl. 365/154

(57) ABSTRACT

A selectable function is provided that permits the impedance of an output driver or an addressable memory device to be configured without adding extra signal connections. The output driver impedance control function of the invention is achieved through the use of the data bus of a memory array for control. The data lines thus serve two purposes one for normal use and the other for control of the impedance. In the invention, the output impedance of each DRAM in a subassembly array that drives a common data bus is individually separately adjusted.

This Application is a Continuation in Part Application of parent application, Ser. No. 10/072,346 Filed Feb. 6, 20002.

### FIELD OF THE INVENTION

The invention relates to the providing of a control function for output drivers of addressable random access memory devices that provides a capability for changing the impedance of an addressable memory output drive circuit without disturbing the contents of the memory device.

### BACKGROUND

In the art, dynamic random access memory arrays, DRAMS, are assembled in arrangements of devices involving data lines and control lines. However, in many constructions both types of lines do not have to connect to each device. As the art is progressing a need is arising for an ability to be able to adjust the output impedance of entire arrays and such a capability would lead to having each device being separately adjustable which in turn would require that the control through each type of line would be desirable at each device.

### SUMMARY OF THE INVENTION

The invention is a selectable function that permits the impedance of an output driver or an addressable memory device to be configured without adding extra signal connections. The output driver impedance control function of the invention is achieved through the use of the data bus of a memory array for control. The data lines thus serve two purposes, one for normal use and the other for control of the impedance. In the invention, the output impedance of each DRAM in a subassembly array that drives a common data bus is individually separately adjusted.

### BRIEF DESCRIPTION OF THE DRAWINGS

FIG. 1 is a perspective illustration of the arrangement of standard in the art Synchronous Dynamic Double Data Rate (SDRAM-DDR) memory array in a typical in the art computer system.

FIGS. 2-5 illustrate the application of the principles of the invention to the control of the impedance of a standard component of SDRAM assemblies, the“off chip”driver(OCD), wherein:

FIG. 2 illustrates a typical DRAM data path through the assembly for writing data.

FIG. 3 illustrates one arrangement of adjustment additions to a typical writing data path such as is shown in FIG. 2 in order to implement the principles of the invention.

FIG. 4 is a timing chart illustrating the effect of the adjustment additions of FIG. 3.

FIG. 5 illustrates an alternate arrangement of adjustment additions to a typical data path such as is shown in FIG. 2 in implementing the principles of the invention.

### DESCRIPTION OF THE INVENTION

As the performance of Dynamic Random Access Memories (DRAMS) in data processing systems moves to ever higher frequencies, precise control of the data input and output in the memory system assembly becomes crucial to ensure that there is reliable transfer into and out of each individual one of the assembly of DRAMS that make up the memory assembly. Included in that precise control is the ability to adjust the impedance of the drivers that move the data in the array. The drivers are separate units, known in the art as “off chip” drivers (OCD)s and receivers (OCR)s.

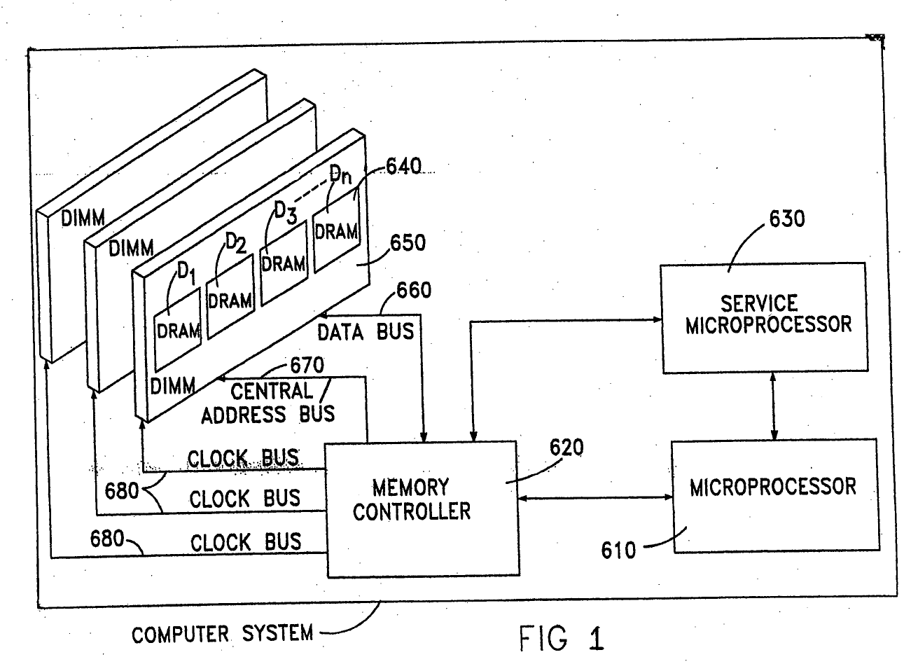

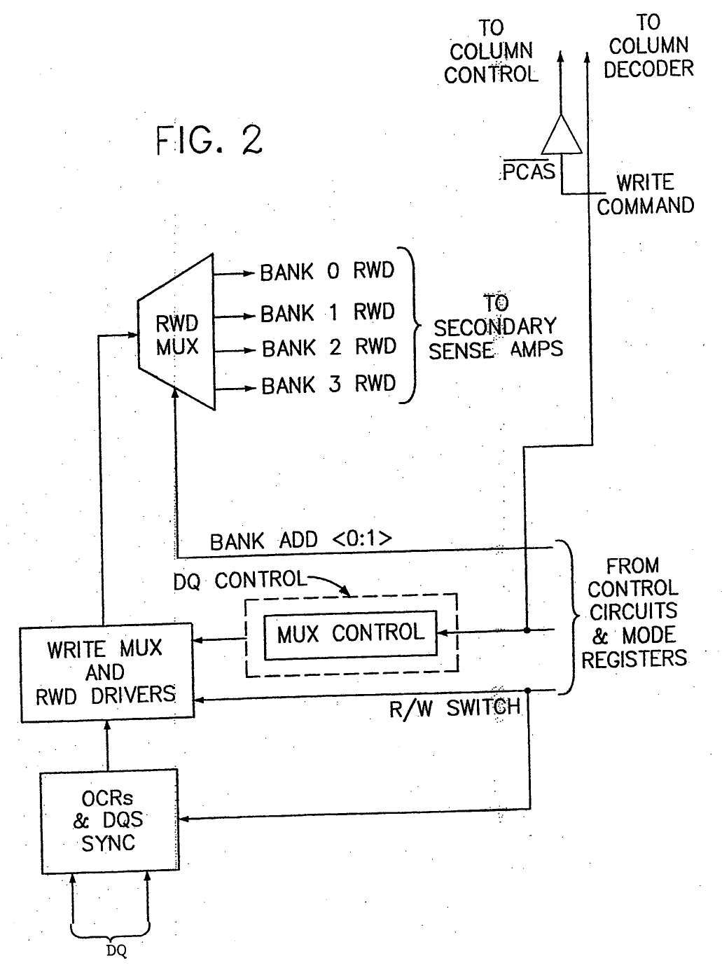

To calibrate the drive strength and impedance of an OCD, DC current measurements can be taken while the OCD is driving a known logical state load and the impedance is adjusted until the required I-V characteristic is obtained. To accomplish such an operation however, the memory controller must be able to establish a desired logical state for the OCD load and then communicate adjustment instructions to the DRAM. The situation is illustrated in connection with FIGS. 2-7 which illustrate the application of the principles of the invention to the control of the impedance of an OCD wherein in FIG. 2 there is illustrated a typical DRAM data path for describing the essential operations in the writing of data. The particular DRAM arrangement in FIGS. 1 and 2 have an example four independent data array banks with the read/write data bus communication channel for the data labelled RWD. The data on the RWD is multiplexed into the arrays.

In FIG. 2 during a write command, the RW switch places the DRAM in a state to receive and store data. Data is input to the DRAM through the DQ Off-Chip receivers at a location labelled (OCR's and DQ's SYNC) and may be synchronized through a data strobe labelled DQS. In the event that the particular architecture is of the type known in the art as the “prefetch” type where several bits of serial data are latched in parallel on consecutive clock cycles, such data may be reordered if necessary in a multiplexer labelled (WRITE MUX). In either case the data is then driven into a bidirectional bus labelled (RWD) and is finally stored in the memory array under circuitry standard in the art for column control and for column decoding, not shown.

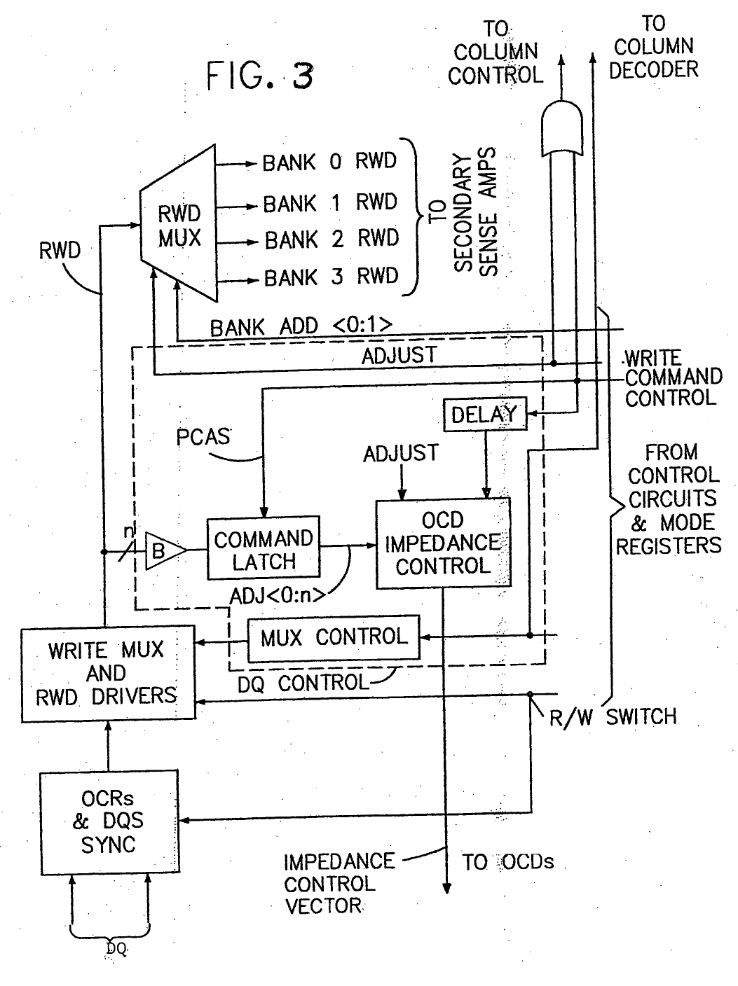

In FIG. 3 the invention is shown through a depiction of the write data path of a DRAM that contains the features of, and operates essentially the same, as the write data path illustrated in connection with FIG. 2. In FIG. 3 in addition there is illustrated within the dotted bordered section, the features used in providing calibration and control of the impedance of off-chip drivers.

Referring to FIG. 3, in the invention an additional control signal is provided, labelled ADJUST. The ADJUST control signal or command is generated by the DRAM control circuits in response to a mode register set command from the memory controller. During the time when the ADJUST command is active, the RWD bus is disconnected from the data array banks and the write command to the column is suppressed. In other words any data in the memory array will remain undisturbed because the memory array is disabled from accepting and storing data.

Therefore, with the ADJUST command active, data can be written onto the RWD bus as with a normal write command, but the data cannot be stored in the memory array. It will be apparent that if at the time it is desired to provide impedance calibration, there is no data in the memory array that it is desirable to remain undisturbed, then any arrangements to inhibit storage would not be required.

In accordance with the invention, under the ADJUST command, there is enablement of added control circuitry, labelled OCD IMPEDANCE CONTROL, that can receive programming instructions from any data on the RWD bus. The OCD IMPEDANCE CONTROL is clocked using the command control signal together with a delayed version of that signal. The OCD IMPEDANCE CONTROL element performs the functions of interpretation of the programming instructions and the generation of vector signals which drive the OCDs and set them to the desired pull up and pull down levels.

An example set of control settings are tabulated in Table 1.

TABLE 1

| | DQ inputs | | |
|---|---|---|---|
| DQ <2> | DQ <1> | DQ <0> | Command |
| X | 0 | 0 | Do Nothing |
| 0 | 0 | 1 | Increase pulldown impedance |
| 0 | 1 | 0 | Decrease pulldown impedance |
| 0 | 1 | 1 | Reset pulldown to default impedance |
| 1 | 0 | 1 | Increase pullup impedance |
| 1 | 1 | 0 | Decrease pullup impedance |
| 1 | 1 | 1 | Reset pullup to default impedance |

In accordance with the invention, with the ADJUST signal activated, a normal write command becomes useable to program the OCD impedance through data received on the DQ inputs.

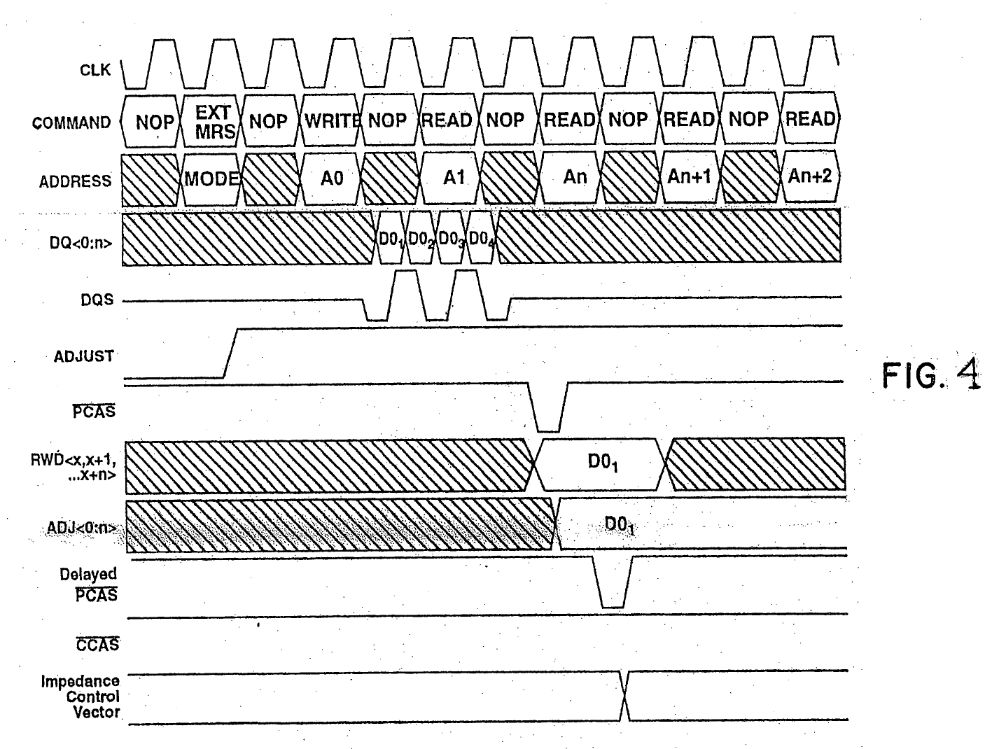

Referring to FIG. 4 a timing chart is provided that shows example timings for the impedance calibration operation. In the chart of FIG. 4 the write command signal is labelled PCAS and the column command is labelled CCAS. In the timing chart of FIG. 4 the standard in the art write data burst architecture of four bits. Only the first bit of a burst from a subset of n DQs is used for programming information. Alternatively, consecutive bits in a burst could contain programming information. Further alternatively, the 2nd, 3rd or 4th bit of a burst could contain the programming information. In the event that just one bit of a burst contains the programming information, the command should send some value for the full burst.

An example protocol for achieving the impedance adjustment as described in connection with FIG. 3 would be as follows.
The extended mode register set (EXTMRS) activates the ADJUST mode.
The ADJUST mode signal places the RWDMUX in a high impedance mode and disables the write command to the column.
The ADJUST mode signal prepares the OCD impedance control circuit to receive adjustment instructions.
A single write command captures the DQs and drives them onto the RWDs.
The first bit of the burst on DQ <0:n>contains the impedance adjustment command. An example command tabulation is shown in TABLE 1.

An alternate option is to write impedance vectors directly to each OCD circuit utilizing the RWD bus to transfer the data to all OCDs and storing the value in a latch at each OCD. This would require that the clocking and mode signals PCAS and ADJUST be distributed to each OCD circuit. Since the existing RWD bus is available to transfer the data to all OCDs the vector bus from the OCD impedance would no longer be needed, thereby saving wiring space.

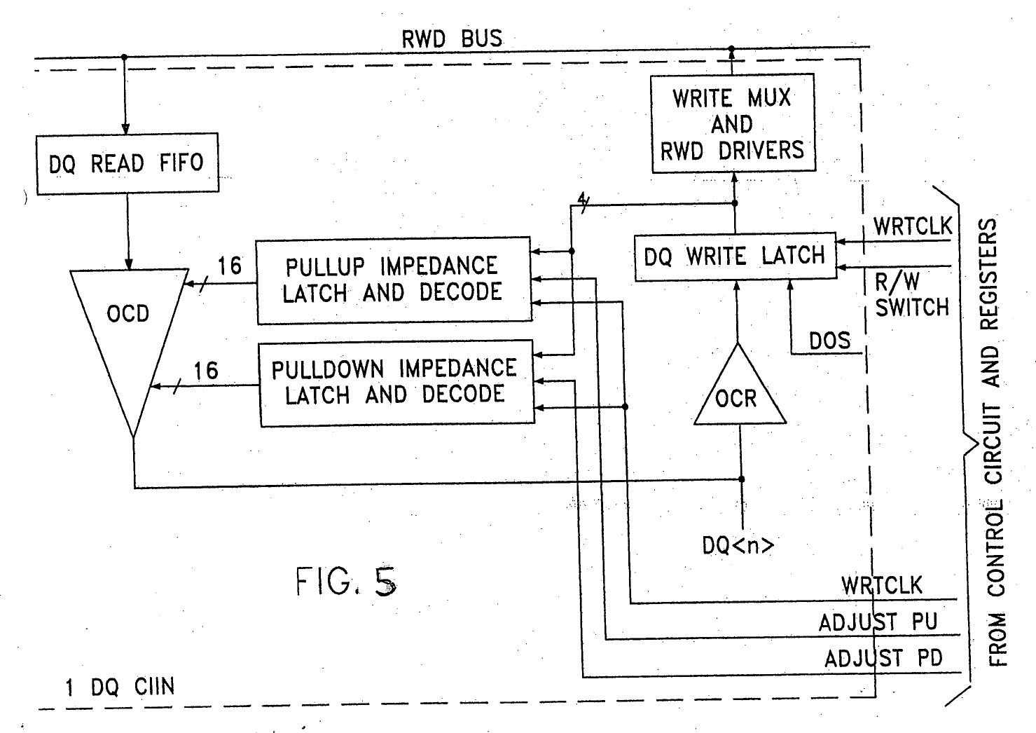

In FIG. 5 there is illustrated an alternate arrangement of adjustment additions to one DQ circuit in a typical data path such as is shown in FIG. 2 in implementing the principles of the invention. Referring to FIG. 5, the arrangement does not involve the RWD bus at all and further allows each OCD to be programmed independently. Two programming mode signals are involved, one labelled ADJUST-PU for adjusting the OCD pullup and another labelled ADJUST-PD for adjusting OCD pulldown. Each can be activated at different times by, a standard in the art, mode register set command. When either mode is active, the write operation to the array is suppressed.

During a write command to the DRAM, the serial data is received by the off-chip receiver labeled OCR at each DQ and is stored in parallel at an element labeled DQ WRITE LATCH. The serial burst length would be four bits. For comparison, in a usual write command the data would be written in parallel over the RWD bus and stored in the memory array however, in this situation the ADJUST-PU or ADJUST-PD mode prevents it. Instead, in this situation, the parallel data is stored directly into the latches located near the OCD. This data contains the value as illustrated through TABLE 1 of the desired impedance for either the pullup or pulldown which is then decoded in selecting the desired OCD impedance.

Therefore with one of the ADJUST-PU or ADJUST-PD signals activated a normal write command can be used to program the OCD impedance with the impedance values provided in a serial burst fashion over the DQ inputs. It should be noted that each OCD receives the impedance values from a unique DQ so that independent programming of different OCDs is enabled. It should also be further noted that there is thus no restriction to a four bit burst length.

An example protocol for achieving the impedance adjustment as described in connection with FIG. 5 would be as follows.
The extended mode register set (EXTMRS) activates the ADJUST-PU or ADJUST PD mode.
The ADJUST-PU or ADJUST-PD mode signal places the RWDMUX in a high impedance mode and disables the write command to the column
A four bit burst is written to each DQ write latch as in a normal write command.
During a DQS to WRTCLK synchronization the four bit burst is transferred to the pullup or pulldown impedance latch and decoder.
The extended mode register set deactivates the ADJUST-PU or ADJUST-PD mode signal.
The memory controller performs the impedance measurement.
The procedure is repeated until the measurement is complete.

What has been described is a function for setting the strength or impedance of output data driver circuits in an addressable memory system. The function can be realized without the addition of external data, addresses, or control signals to the memory device.

1. In an addressable random access memory having a plurality of data array banks arranged in columns and rows, having provision for read and write signals to said banks in separate command cycles multiplexed into a common data bus under control of the control and decoding circuitry of said columns and having power driver elements for each of said banks, the improvement for calibration of the impedance of said driver elements comprising:
means for providing, during a write command cycle, an adjust signal operable to disable input from said common data bus into said array bank, and to disconnect said write command signal from the circuitry of said columns,
means for delivering impedance control vector signals, indicating at least one of change of magnitude and of satisfaction with the present impedance state, to each of said power driver elements, and,
means for producing impedance control instructions on said common data bus, said instructions being operable to select from tabulated values of said at least one of change of magnitude and of satisfaction with the present impedance state, and delivering said instructions to said impedance control vector delivery means.

2. The addressable random access memory improvement of claim 1 wherein said data array banks are of the dynamic random access type known in the art as DRAMs.

3. An addressable random access memory array of the type having
a plurality of data banks arranged in columns and rows,
provision for read and write signals to said banks being in separate command cycles,
said read and write signals being multiplexed into a common data bus under control of the control and decoding circuitry of said columns, and,
said array having power driver elements for each of said banks,
the improvement for calibration of the impedance of said driver elements comprising:
means for providing, during a write command cycle, an adjust signal,
said adjust signal being operable
to disable input from said common data bus into said array bank, and,
to disconnect said write command signal from the circuitry of said columns,
means for delivering impedance control vector signals to each of said power driver elements
said impedance control vector signals indicating at least one of change of magnitude and of satisfaction with the present impedance state, and,
means for producing impedance control instructions on said common data bus,
said impedance control instructions operable
for selection from tabulated values of said at least one of
change of magnitude and of satisfaction with the present impedance state, and
delivering said instructions to said impedance control vector delivery means.

4. The addressable random access memory improvement of claim 3 wherein said data array banks are of the dynamic random access type known in the art as DRAMs.

5. The method of calibrating the impedance of power driving elements that drive read and write operations in an addressable random access memory array having a plurality of data banks arranged in columns and rows, having provision for read and write signals to said data banks in separate command cycles multiplexed onto a common data bus under control of the control and decoding circuitry of said columns and having power driving elements for each of said data banks,
comprising the steps of:
providing, during a write command cycle, an adjust signal, operable to disable input from said common data bus into said data banks, and to disconnect said write command signal from the circuitry of said columns,
producing impedance control instructions, said instructions being operable to select from tabulated values of said at least one of change of magnitude and of satisfaction with the present impedance state, and,
delivering said instructions to said each of said power driving elements.

6. The method of calibrating the impedance of power driving elements of claim 5 wherein: in said step of producing impedance control instructions, the added step of delivering said impedance control instructions in the form of vector signals, indicating at least one of change of magnitude and of satisfaction with the present impedance state, to each of said power driving elements.

7. The method of calibrating the output impedance of separate power drivers that drive the read and write operations in an addressable random access memory array, said memory array being of the type wherein:
there is a plurality of data banks arranged in columns and rows:
there are read and write signals to said data banks in separate command cycles multiplexed onto a common data bus under control of the control and decoding circuitry of said columns:
and there is a separate power driving element for each bank of said data banks,
comprising the steps of:
providing, during a write command cycle, an adjust signal,
said adjust signal being operable
to disable input from said common data bus into said data banks, and,
to disconnect said write command signal from the circuitry of said columns,
producing impedance control instructions,
said impedance control instructions being operable
to select from tabulated values of at least one
of change of impedance magnitude, and,
of satisfaction with the present impedance state, and,
delivering said impedance control instructions to
each of said separate power driving elements.

8. The method of calibrating the impedance of power driving elements of claim 7 wherein: in said step of producing impedance control instructions, the added step of delivering said impedance control instructions in the form of vector signals, indicating at least one of change of magnitude and of satisfaction with the present impedance state, to each of said power driving elements.

9. In an addressable random access memory array having a plurality of data banks arranged in columns and rows, wherein there is provision for read and write signals to said banks in separate command cycles multiplexed onto a common data bus and there are separate power driver elements for each of said banks,
the improvement for calibration of the impedance of each driver element of said driver elements comprising:
means for providing, during a write command cycle, adjust up and adjust down signals operable to provide clocked latched and decoded input to each said driver element as impedance control vector signals, indicating at least one of change of magnitude and of satisfaction with the present impedance state, to each of said power driving elements.

10. The addressable random access memory improvement of claim 9 wherein said data array banks are of the dynamic random access type known in the art as DRAMs.

11. In an addressable random access memory array,
said array including
a plurality of data banks arranged in columns and rows,
provision for delivery of read and write signals to said banks in
separate command cycles multiplexed onto a common data bus, and,
a separate power driving element for each of said data banks,
the improvement for calibration of the impedance of said driver elements comprising:
means for providing an adjust up and an adjust down calibrating adjustment signal to each of said driver elements, during said command cycle for said write signal,
said adjust up and an adjust down calibrating adjustment signal being operable at each said driver element as an impedance control vector signal, indicating at least one of change of magnitude and of satisfaction with the present impedance state.

12. The addressable random access memory improvement of claim 11 wherein said data array banks are of the dynamic random access type known in the art as DRAMs.
